(19) United States
(12) Patent Application Publication
(10) Pub. No.: US 2025/0219014 A1
(43) Pub. Date: Jul. 3, 2025

(54) SEMICONDUCTOR REFLOW APPARATUS

(71) Applicant: SAMSUNG ELECTRONICS CO., LTD., SUWON-SI (KR)

(72) Inventors: Chaein Moon, Suwon-si (KR); Gongmyeong Kim, Suwon-si (KR); Sunchul Kim, Suwon-si (KR); Taejae Park, Suwon-si (KR); Hyeonrae Cho, Suwon-si (KR)

(21) Appl. No.: 19/003,671

(22) Filed: Dec. 27, 2024

(30) Foreign Application Priority Data
Dec. 28, 2023 (KR) 10-2023-0195361

(51) Int. Cl. H01L 23/00

(52) U.S. Cl. CPC H01L 24/75; H01L 2224/75265; H01L 2224/7555; H01L 2224/75651; H01L 2224/7598; H01L 2924/40

(57) ABSTRACT

A semiconductor reflow apparatus includes a conveyor comprising a laterally moveable surface configured to move in a first direction, a pickup tool including a head disposed above the conveyor, and an induction heating coil configured to generate a magnetic field in a direction passing through a surface of the conveyor, wherein the pickup tool is further configured to move the head in a vertical direction toward the conveyor.

### CROSS-REFERENCE TO RELATED APPLICATION

This application is based on and claims priority under 35 U.S.C. § 119 to Korean Patent Application No. 10-2023-0195361, filed on Dec. 28, 2023, in the Korean Intellectual Property Office, the disclosure of which is incorporated by reference herein in its entirety.

### BACKGROUND

### 1. Technical Field

The inventive concept relates to a semiconductor reflow apparatus, and more particularly, to a semiconductor reflow apparatus including a pickup tool.

### 2. Discussion of Related Art

A process of packaging a semiconductor chip may include an assembly process, in which a conductive bump functioning as a terminal for electrical connection to the outside may be attached to a semiconductor chip, and a mounting process, in which the semiconductor chip having the conductive bump may be mounted on a printed circuit board. After the assembly and mounting processes, a process of reflowing the conductive bump may be performed by heating the conductive bump.

### SUMMARY

The inventive concept provides a semiconductor reflow apparatus including a pickup tool.

The inventive concept provides a semiconductor reflow apparatus including a conveyor, a pickup tool, and an induction coil, which may efficiently heat conductive bumps.

The inventive concept also provides a semiconductor reflow apparatus for applying pressure between a semiconductor chip and a package substrate during a reflow process.

The inventive concept is not limited to those mentioned above, and the inventive concept that has not been mentioned will be clearly understood by one of skill in the art from the description below.

According to an aspect of the inventive concept, there is provided a semiconductor reflow apparatus. The semiconductor reflow apparatus includes a conveyor comprising a laterally moveable surface configured to move in a first direction, a pickup tool including a head disposed above the conveyor, and an induction heating coil configured to generate a magnetic field in a direction passing through a surface of the conveyor, wherein the pickup tool is further configured to move the head to press the package substrate in a vertical direction toward the conveyor.

According to another aspect of the inventive concept, there is provided a semiconductor reflow apparatus for melting a plurality of bumps disposed between a package substrate and a plurality of chip dies. The semiconductor reflow apparatus includes a conveyor configured to have the package substrate mounted on the conveyor and transport the package substrate in a first direction, a pickup tool including a head and a traveling rail, the head being configured to capture the plurality of chip dies, and the traveling rail extending in the first direction, providing a movement path for the head, and being disposed above the conveyor, and an induction heating coil configured to heat the plurality of bumps through eddy current and bond the plurality of chip dies to the package substrate, wherein the pickup tool is configured to mount the plurality of chip dies on the package substrate mounted on the conveyor, and the pickup tool is further configured to press the plurality of chip dies captured by the head into the package substrate in a vertical direction in a process of heating the plurality of bumps.

According to a further aspect of the inventive concept, there is provided a semiconductor reflow apparatus for melting a plurality of bumps between a package substrate and a plurality of chip dies. The semiconductor reflow apparatus includes a conveyor configured to have the package substrate mounted on the conveyor, the conveyor including a pair of power shafts spaced apart from each other in a first direction and a belt mounted on the pair of power shafts, a pickup tool including a head configured to capture the plurality of chip dies, the pickup tool being configured to mount the plurality of chip dies on the package substrate on the conveyor, an induction heating coil configured to heat the plurality of bumps through eddy current and bond the plurality of chip dies to the package substrate, and a power supply electrically connected to the induction heating coil, wherein, when a portion of the belt where the package substrate is located while the plurality of chip dies are being bonded to the package substrate is a contact section of the belt, the induction heating coil overlaps the contact section of the belt in a vertical direction, and the pickup tool is further configured to press the plurality of chip dies captured by the head into the package substrate in the vertical direction while the power supply is applying alternating current to the induction heating coil.

### BRIEF DESCRIPTION OF THE DRAWINGS

Embodiments will be more clearly understood from the following detailed description taken in conjunction with the accompanying drawings in which:

FIG. 1 is a schematic block diagram of a semiconductor package system according to an embodiment;

FIG. 2 is a schematic perspective view of a portion of a semiconductor reflow apparatus of the semiconductor package system of FIG. 1;

FIG. 3 is a schematic plan view of a portion of the semiconductor reflow apparatus of FIG. 2;

FIG. 4 is a schematic cross-sectional view of a portion of the semiconductor reflow apparatus of FIG. 2, taken along line X1-X1′in FIG. 2;

FIG. 5 is a schematic cross-sectional view of a portion of the semiconductor reflow apparatus of FIG. 2, taken along line Y1-Y1′ in FIG. 2;

FIG. 6 is a schematic perspective view of a semiconductor reflow apparatus according to an embodiment;

FIG. 7 is a schematic cross-sectional view of a portion of the semiconductor reflow apparatus of FIG. 6, taken along line X2-X2′ in FIG. 6;

FIG. 8 is a schematic cross-sectional view of a portion of the semiconductor reflow apparatus of FIG. 6, taken along line Y2-Y2′ in FIG. 6;

FIG. 9 is a schematic block diagram of a semiconductor package system according to an embodiment;

FIG. 10 is a schematic perspective view of a portion of a semiconductor reflow apparatus of the semiconductor package system of FIG. 9;

FIG. 11 is a schematic cross-sectional view of a portion of the semiconductor reflow apparatus of FIG. 10, taken along line X3-X3′ in FIG. 10;

FIG. 12 is a schematic cross-sectional view of a portion of the semiconductor reflow apparatus of FIG. 10, taken along line Y3-Y3′ in FIG. 10;

FIG. 13 is a schematic perspective view of a portion of a semiconductor reflow apparatus according to an embodiment;

FIG. 14 is a schematic perspective view of a portion of a semiconductor reflow apparatus according to an embodiment;

FIG. 15 is a schematic perspective view of a portion of a semiconductor reflow apparatus according to an embodiment;

FIG. 16A, FIG. 16B, FIG. 16C, and FIG. 16D are diagrams illustrating sequential stages in a reflow process of a semiconductor reflow apparatus, according to an embodiment; and

FIG. 17A, FIG. 17B, FIG. 17C, FIG. 17D, and FIG. 17E are diagrams illustrating sequential stages in a reflow process of a semiconductor reflow apparatus, according to an embodiment.

### DETAILED DESCRIPTION

Hereinafter, embodiments will be described in detail with reference to the accompanying drawings. The same reference numerals may be used for the same components in the drawings, and redundant descriptions thereof may be omitted.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

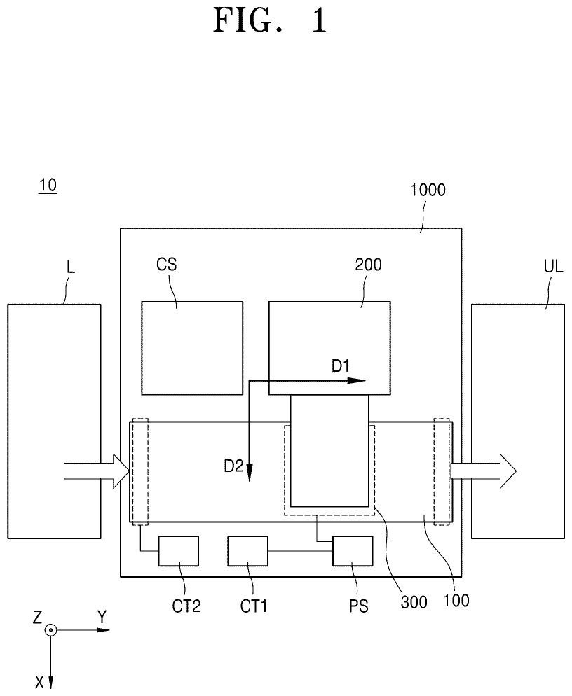

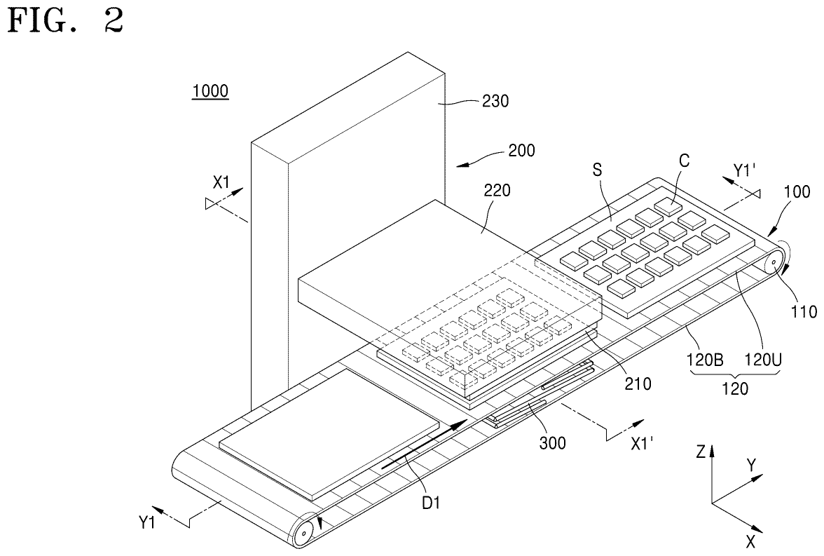

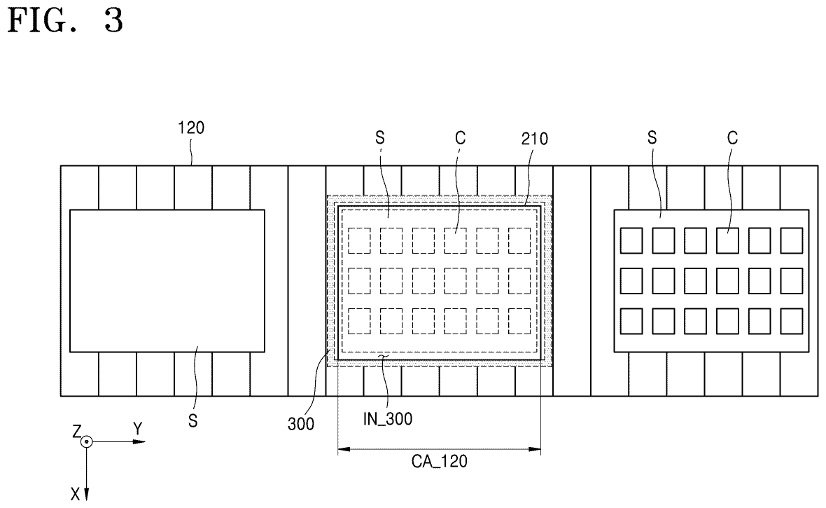

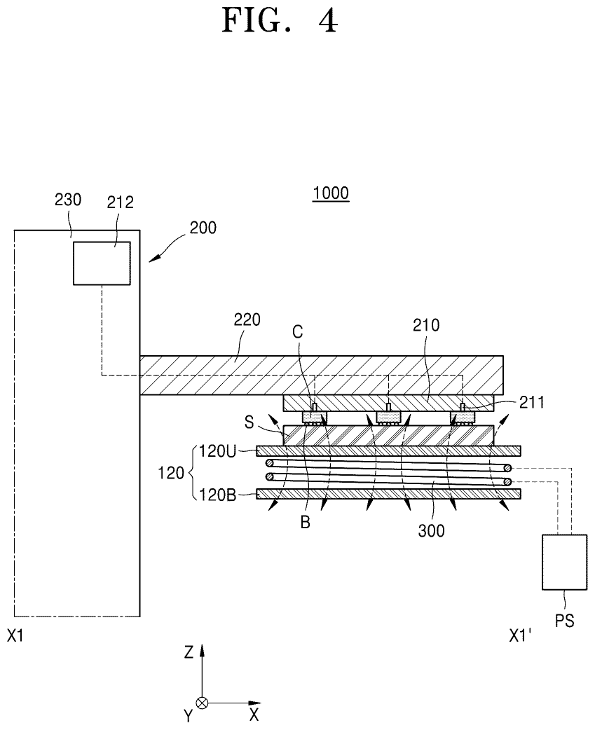

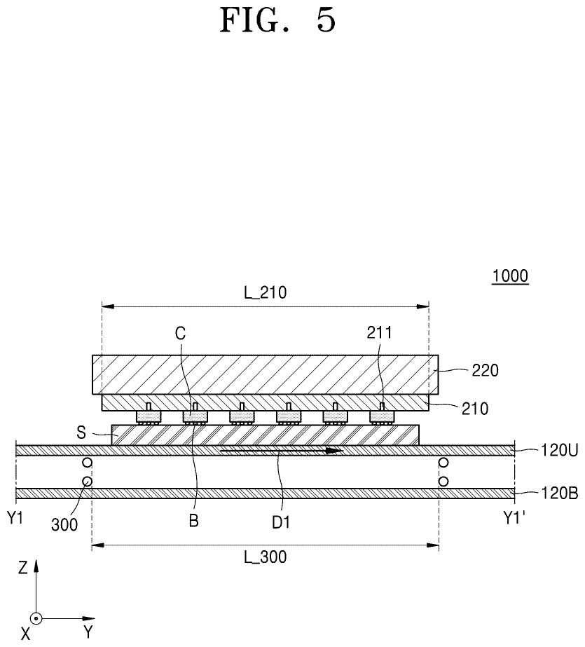

FIG. 1 is a schematic block diagram of a semiconductor package system 10 according to an embodiment. FIG. 2 is a schematic perspective view of a semiconductor reflow apparatus 1000 of the semiconductor package system 10 of FIG. 1. FIG. 3 is a schematic plan view of a portion of the semiconductor reflow apparatus 1000 of FIG. 2. FIG. 4 is a schematic cross-sectional view of a portion of the semiconductor reflow apparatus 1000 of FIG. 2, taken along line X1-X1′in FIG. 2. FIG. 5 is a schematic cross-sectional view of a portion of the semiconductor reflow apparatus 1000 of FIG. 2, taken along line Y1-Y1′ in FIG. 2.

Referring to FIG. 1, the semiconductor package system 10 may include a loader L, the semiconductor reflow apparatus 1000, and an unloader UL. The loader L, the semiconductor reflow apparatus 1000, and the unloader UL may be sequentially disposed. For example, the loader L may be disposed at a first side of the semiconductor reflow apparatus 1000, and the unloader UL may be disposed at a second side of the semiconductor reflow apparatus 1000 disposed opposite to the first side of the semiconductor reflow apparatus 1000. The loader L may transfer a package substrate (S in FIG. 4) to the semiconductor reflow apparatus 1000. For example, the loader L may transfer the package substrate S to a conveyor 100 of the semiconductor reflow apparatus 1000.

The semiconductor reflow apparatus 1000 may perform a mounting operation and a reflow operation. The mounting operation may include mounting a plurality of chip dies (C in FIG. 4) on a package substrate. The reflow operation may include melting a plurality of conductive bumps (B in FIG. 4). For example, the semiconductor reflow apparatus 1000 may mount chip dies on a package substrate on the conveyor 100 and may bond the chip dies to the package substrate by melting conductive bumps. A semiconductor package manufactured by the semiconductor reflow apparatus 1000 by bonding the chip dies to the package substrate may be transferred to the unloader UL.

Herein, the mounting operation and the reflow operation may be combined into and referred to as an operation of bonding a plurality of chip dies to a package substrate or a reflow process.

The semiconductor reflow apparatus 1000 is described in detail below with reference to FIGS. 2 to 5.

Referring to FIGS. 2 to 5, the semiconductor reflow apparatus 1000 may include the conveyor 100, a pickup tool 200, and an induction heating coil 300.

Unless stated otherwise, a direction that is parallel with a top surface of the conveyor 100 may be referred to as a first horizontal direction (the X direction), a direction that is perpendicular to the top surface of the conveyor 100 may be referred to as the vertical direction (the Z direction), and a direction that is perpendicular to the first horizontal direction (the X direction) and the vertical direction (the Z direction) may be referred to as a second horizontal direction (the Y direction). A direction combining the first horizontal direction (the X direction) and the second horizontal direction (the Y direction) may be referred to as a horizontal direction.

The conveyor 100 may have the package substrate S mounted thereon and may transport the package substrate S in a first direction D1. The conveyor 100 may include a laterally moveable surface configured to transport the package substrate S in a first direction D1. For example, the conveyor 100 may include a pair of power shafts 110 and a belt 120. The power shafts 110 may be spaced apart from each other in the first direction D1. The power shafts 110 may rotate in the same direction with respect to a long axis. The belt 120 may define a longitudinal path of the conveyor 100 for conducting the package substrate S. The belt 120 may be mounted on the pair of power shafts 110. The belt 120 may rotate as the pair of power shafts 110 rotates. The belt 120 may carry the package substrate S along a length of the conveyor 100. The belt 120 may be variously provided. For example, the belt 120 may be, for example, a rubber belt, a polyvinyl chloride belt, a metal belt, or a modular plastic belt.

In some embodiments, the package substrate S may be fixed to the belt 120 and may thus move along the longitudinal path of the conveyor 100 with the rotation of the belt 120. In some embodiments, the belt 120 may include a jig that physically holds the package substrate S or a vacuum stage that holds the package substrate S with vacuum pressure. In this way, the substrate S may be secure to the belt 120.

In some embodiments, the belt 120 may be conceptually divided into an upper section 120U and a lower section 120B. That is, the belt 120 may include the upper section 120U and the lower section 120B. The upper section 120U of the belt 120 may be a portion disposed above the power shafts 110 and the lower section 120B of the belt 120 may be a portion disposed below the power shafts 110. The upper section 120U and the lower section 120B of the belt 120 may be spaced apart from each other by the diameter of each of the power shafts 110. That is, the upper section 120U and the lower section 120B are relative positions, and a portion of the belt 120 may repeatedly rotate between being disposed at the upper section 120U and the lower section 120B.

The package substrate S may be mounted on the belt 120 on the upper section 120U of the belt 120. The mounting of the package substrate S may include mounting a plurality of chip dies C. A reflow operation may be performed on the plurality of chip dies C mounted on the upper section 120U of the belt 120. The package substrate S may be dismounted from the upper section 120U, and the package substrate S may not be mounted on the lower section 120B of the belt 120.

In some embodiments, a plurality of package substrates S may be mounted on the belt 120. The length of the belt 120 in the first direction D1 may be greater than the length of a package substrate S in the first direction D1. For example, two or more package substrates S may be mounted on the upper section 120U of the belt 120. Because a plurality of package substrates S may be carried by the conveyor 100, an elapsed time of the reflow process of the semiconductor reflow apparatus 1000 may be shortened.

The pickup tool 200 may transport the chip dies C from a chip shuttle CS to a package substrate S. For example, an arrangement of the chip dies C disposed in the chip shuttle CS may be a same arrangement in which the chip dies C are to be mounted on the package substrate S. In other words, the pickup tool 200 may transfer the chip dies C to the package substrate S in the same arrangement as the chip dies C on the chip shuttle CS.

The pickup tool 200 may include a head 210, a head driver 220, and a body 230. The head 210 may be configured to capture and release the chip dies C. The head 210 may be attached to a bottom surface of the head driver 220. The head driver 220 may be configured to move the head 210. The head driver 220 may be configured to move the head 210 in the vertical direction (the Z direction) and/or in a second direction D2. In other words, the head 210 may be attached to the head driver 220, and the head driver 220 may change a position of the head 210. Here, the second direction D2 may be perpendicular to the first direction D1, and the first direction D1 may be a direction in which the package substrate S is transported.

The head 210 may capture and release the chip dies C, enabling the chip dies C to be attached to the head 210 or be detached from the head 210. For example, the head 210 may include a plurality of vacuum grooves 211. The vacuum grooves 211 may be disposed in the bottom of the head 210. The pickup tool 200 may generate negative pressure in the vacuum grooves 211 such that the chip dies C may be attached to the head 210. The pickup tool 200 may remove the negative pressure from the vacuum grooves 211 such that the chip dies C may be detached from the head 210.

A width of each of the vacuum grooves 211 may be smaller than a width of each of the chip dies C. When negative pressure is generated in the vacuum grooves 211, each of the chip dies C may overlap a respective vacuum groove of the vacuum grooves 211 in the vertical direction (the Z direction). In other words, when each of the chip dies C overlaps a respective vacuum groove of the vacuum grooves 211 in which negative pressure is formed, the chip dies C may be attached to the head 210.

In some embodiments, an area of the bottom surface of the head 210 may be greater than or equal to the area of a top surface of the package substrate S. For example, the chip dies C to be mounted on the package substrate S may be simultaneously attached to the head 210 such that the pickup tool 200 may simultaneously mount the chip dies C on the package substrate S. When the pickup tool 200 simultaneously mounts the chip dies C on the package substrate S, a reflow process time may be shortened.

In some embodiments, the length of the head 210 in the second direction D2 may be less than the length of the package substrate S in the second direction D2 (see FIG. 4), and the length of the head 210 in the first direction D1 may be greater than or equal to the length of the package substrate S in the first direction D1 (see FIG. 5). A set of chip dies C arranged in line in the first direction D1 among the chip dies C to be mounted on the package substrate S may be simultaneously attached to the head 210 and mounted on the package substrate S.

The head driver 220 may position the head 210 to be disposed above the chip shuttle CS such that the chip dies C arranged in the chip shuttle CS may be attached to the head 210. For example, as shown in FIG. 1 and FIG. 2, when the chip shuttle CS is disposed at a side of the body 230, the head driver 220 may rotate clockwise or counterclockwise to locate the head 210 above the chip shuttle CS. For example, the body 230 may rotate about its vertical axis, and the head driver 220, extending from the body 230, may be disposed above the chip shuttle CS. In another example, when the chip shuttle CS is disposed inside, e.g., below, the body 230, the head driver 220 may move the head 210 in a direction opposite to the second direction D2 to position the head 210 above the chip shuttle CS.

In some embodiments, the head driver 220 may move the head 210 in the vertical direction (the Z direction) such that the chip dies C attached to the head 210 may be mounted on the package substrate S. For example, when the head driver 220 moves in the vertical direction (the Z direction) along the body 230, the chip dies C attached to the head 210 may be disposed on the package substrate S.

In some embodiments, the head driver 220 may include a pressing unit (not shown), which may move in the vertical direction (the Z direction) from the bottom of the head driver 220. The head 210 may be attached to a bottom surface of the pressing unit of the head driver 220 and may be moved along with the movement of the pressing unit in the vertical direction (the Z direction). In other words, the head driver 220 may move the pressing unit to protrude downwards in the vertical direction (the Z direction such that the chip dies C of the head 210 are located on the package substrate S.

In some embodiments, the head driver 220 may include a sensor (not shown). The sensor may recognize a reference point such as a vision mark. The reference point may be disposed on, for example, the substrate S of the chip dies C. The pickup tool 200 may readjust the position of the head 210 based on the position of the reference point recognized by the sensor.

The body 230 may include a negative pressure generator 212. The negative pressure generator 212 may be connected to the vacuum grooves 211 of the head 210. The negative pressure generator 212 may generate a negative pressure in the vacuum grooves 211. In some embodiments, the body 230 may include a plurality of modulators (not shown). The modulators may provide power to the head driver 220. For example, the modulators may provide the head driver 220 with power for the movement of the head driver 220 in the vertical direction (the Z direction), the movement of the head 210 in the second direction D2, and the rotation of the head driver 220 and/or the body 230.

In some embodiments, the semiconductor reflow apparatus 1000 may include a controller (not shown). For example, the controller may be disposed in the body 230. The controller may control the pickup tool 200 to mount the chip dies C on the package substrate S and to press a plurality of conductive bumps B. In some embodiments, the controller may control the head driver 220 and the head 210, based on position information regarding the head 210 and input information of the sensor of the head driver 220. The controller may control the negative pressure generator 212 and may control attachment and detachment of the chip dies C to and from the head 210. The controller may control the modulators to control the position of the head 210.

In some embodiments, the pickup tool 200 may be configured to mount the chip dies C on the package substrate S on the conveyor 100. The package substrate S may be mounted on the conveyor 100 in an empty state in which the chip dies C are not mounted on the package substrate S. As the package substrate S moves along the conveyor 100, the chip dies C may be mounted on the package substrate S by the pickup tool 200.

In some embodiments, the pickup tool 200 may be configured such that the head 210 of the pickup tool 200 may press the package substrate S in the vertical direction (the Z direction) in a process of mounting the chip dies C on the package substrate S. For example, even after the chip dies C attached to the head 210 contact the package substrate S, the pickup tool 200 may move the head 210 downwards in the vertical direction (the Z direction).

In some embodiments, the pickup tool 200 may be configured such that the head 210 presses the package substrate S in the vertical direction (the Z direction) while the conductive bumps B are being heated. For example, an alternating current may be applied to the induction heating coil 300, the pickup tool 200 may move the head 210 downwards in the vertical direction (the Z direction), and the conductive bumps B may be heated to a melting point.

As the head 210 moves downwards in the vertical direction (the Z direction), the head 210 may indirectly apply pressure to the package substrate S. During this process, the conductive bumps B disposed below the chip dies C may be pressed into the package substrate S. Through the process in which the pickup tool 200 presses the package substrate S, the melting point of the conductive bumps B may be lowered, and a quality of a reflow process may be increased. The relationship between melting point and pressure is generally considered to follow the Lindemann criterion.

The induction heating coil 300 may have an inner through space IN_300 and may include a single layer or layers (see FIG. 3). The induction heating coil 300 may be connected to a power supply PS. The induction heating coil 300 and may receive current applied from the power supply PS. When current is applied to the induction heating coil 300, the induction heating coil 300 may form a magnetic field according to Ampere's law.

The inner through space IN_300 of the induction heating coil 300 may have a rectangular shape, however the inner through space IN_300 of the induction heating coil 300 is not limited thereto and may have other shapes, such as a circular shape or polygonal shape.

When a current is applied to the induction heating coil 300, a magnetic field may be formed in a direction passing through the inner through space IN_300 of the induction heating coil 300. When the power supply PS applies an alternating current to the induction heating coil 300, the strength and direction of a magnetic field formed around the induction heating coil 300 may vary with the alternating current. In other words, when the power supply PS applies alternating current to the induction heating coil 300, a density of magnetic flux passing through the inner through space IN_300 of the induction heating coil 300 may be controlled.

When the strength of the magnetic field around the induction heating coil 300 changes, an eddy current may be generated in a metal around the induction heating coil 300. The eddy current may increase a temperature of the metal in which the eddy current occurs. For example, an eddy current may be generated in the conductive bumps B by the induction heating coil 300, and the temperature of the conductive bumps B may be increased by the induction heating coil 300.

The semiconductor reflow apparatus 1000 may apply an alternating current to the induction heating coil 300, which may increase the temperature of the conductive bumps B. The semiconductor reflow apparatus 1000 may heat the induction heating coil 300 and may not heat a surrounding structure. In other words, the semiconductor reflow apparatus 1000 may rapidly melt the conductive bumps B through induction heat in a small area, and may reduce a reflow process time. For example, the semiconductor reflow apparatus 1000 may melt the conductive bumps B in about 20 seconds.

In addition, the semiconductor reflow apparatus 1000 may limit an exposure time of the chip dies C and the package substrate S to high temperature, which may inhibit defects from occurring in a semiconductor package due to deformation of the chip dies C and/or the package substrate S.

In some embodiments, the induction heating coil 300 may be disposed below the upper section 120U of the belt 120. The induction heating coil 300 may be spaced apart from the belt 120. In other words, the induction heating coil 300 may be stationary. The movement of the belt 120 may move the substrate S through a magnetic field formed around the induction heating coil 300.

For example, the induction heating coil 300 may be disposed between the upper section 120U and the lower section 120B of the belt 120. However, embodiments are not limited thereto. The induction heating coil 300 may be disposed below the lower section 120B of the belt 120, that is, below the conveyor 100.

A portion of the belt 120, in which the package substrate S is located while the chip dies C are being bonded to the package substrate S, may be referred to as a contact section CA_120 of the belt 120 (see FIG. 3). For example, the contact section CA_120 of the belt 120 may be a portion in which the pickup tool 200 mounts the chip dies C on the package substrate S. For example, the contact section CA_120 of the belt 120 may be a portion in which the head 210 of the pickup tool 200 presses the package substrate S.

In some embodiments, the belt 120 may be stationary while the pickup tool 200 is pressing the package substrate S, and the area of the contact section CA_120 of the belt 120 may be substantially the same as the area of the package substrate S.

In some embodiments, the belt 120 and the head 210 may move in the first direction D1 while the pickup tool 200 is pressing the package substrate S, and the area of the contact section CA_120 of the belt 120 may be greater than the area of the package substrate S.

In some embodiments, the inner through space IN_300 of the induction heating coil 300 may be disposed below the contact section CA_120 of the belt 120. While the pickup tool 200 is pressing the package substrate S, the induction heating coil 300 may overlap the contact section CA_120 of the belt 120 and increase the temperature of the conductive bumps B.

In some embodiments, in a plan view (e.g., FIG. 3), the area of the inner through space IN_300 of the induction heating coil 300 may be greater than or equal to the area of the head 210 of the pickup tool 200. In a reflow process, the head 210 may be disposed above the induction heating coil 300 to completely overlap the induction heating coil 300 such that the chip dies C attached to the head 210 may be heated by the induction heating coil 300.

In some embodiments, as shown in FIG. 4, the induction heating coil 300 may be arranged such that a magnetic field passing through the inner through space IN_300 of the induction heating coil 300 may be directed to the upper section 120U of the belt 120. In other words, the induction heating coil 300 may have a spiral shape extending substantially in the vertical direction (the Z direction).

However, embodiments are not limited thereto. The induction heating coil 300 may be arranged such that a magnetic field passing through the inner through space IN_300 of the induction heating coil 300 may be in the first direction D1. In other words, the induction heating coil 300 may have a spiral shape extending substantially in the horizontal direction.

In some embodiments and referring to FIG. 5, a length L_300 of the induction heating coil 300 in the first direction D1 may be greater than a length L_210 of the head 210 of the pickup tool 200 in the first direction D1. The length of the induction heating coil 300 in the second direction D2 may be greater than the length of the head 210 of the pickup tool 200 in the second direction D2 (see FIG. 1 and FIG. 4).

In some embodiments and referring to FIG. 1, the semiconductor reflow apparatus 1000 may further include a first controller CT1 and a second controller CT2.

The first controller CT1 may be configured to control the power supply PS. The first controller CT1 may selectively control the power supply PS to apply alternating current to the induction heating coil 300. For example, the first controller CT1 may turn on or off the power supply PS.

In some embodiments, when the first controller CT1 turns on the power supply PS, alternating current may be applied to the induction heating coil 300, and the conductive bumps B around the induction heating coil 300 may be heated. When the head 210 of the pickup tool 200 mounts the chip dies C on the package substrate S, the first controller CT1 may turn on the power supply PS. The semiconductor reflow apparatus 1000 may heat the conductive bumps B using the induction heating coil 300 when the pickup tool 200 mounts the chip dies C on the package substrate S and applies pressure to the conductive bumps B. The chip dies C may be bonded to the package substrate S by the conductive bumps B, which have been heated by the induction heating coil 300 and pressed by the pickup tool 200.

The second controller CT2 may be configured to control an operation of the conveyor 100. For example, the second controller CT2 may control the rotation speed of the power shafts 110 of the conveyor 100. In other words, the second controller CT2 may control the speed of the belt 120 and the transportation of the package substrate S mounted thereon by controlling the rotation of the power shafts 110.

In some embodiments, when the second controller CT2 stops the rotation of the power shafts 110, the belt 120 may stop, causing the transportation of the package substrate S to stop. The second controller CT2 may stop the rotation of the power shafts 110 and the head 210 of the pickup tool 200 may mount the chip dies C on the package substrate S and the conductive bumps B may be heated.

For example, when the package substrate S is disposed in the contact section CA_120 of the belt 120, the second controller CT2 may stop the rotation of the power shafts 110, thereby stopping the transportation of the package substrate S. At this time, the head 210 of the pickup tool 200 may mount the chip dies C on the package substrate S that is in a stopped state. When mounting and reflow operations are completed through the pickup tool 200 and the induction heating coil 300, the second controller CT2 may restart the rotation of the power shafts 110 to resume the transportation of the package substrate S. Bonding between the chip dies C and the package substrate S may be carried out while the package substrate S is in the stopped state, and alignment between the chip dies C and the package substrate S may be secured.

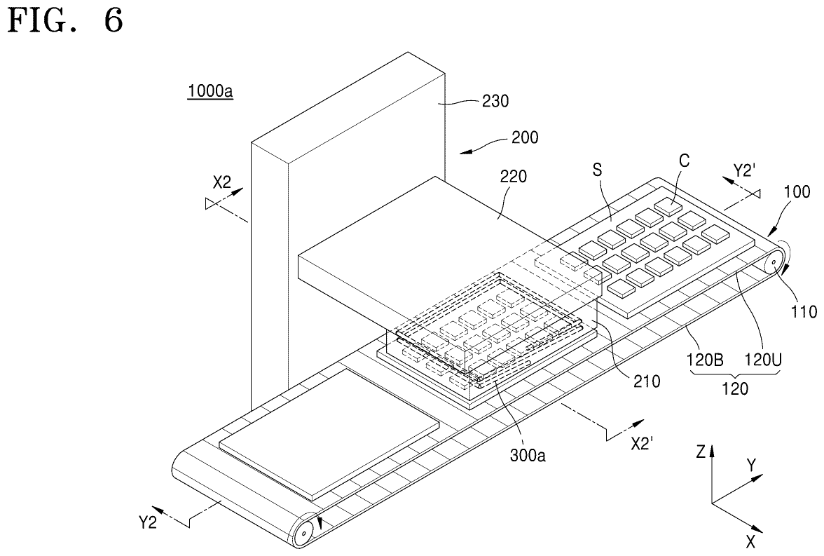

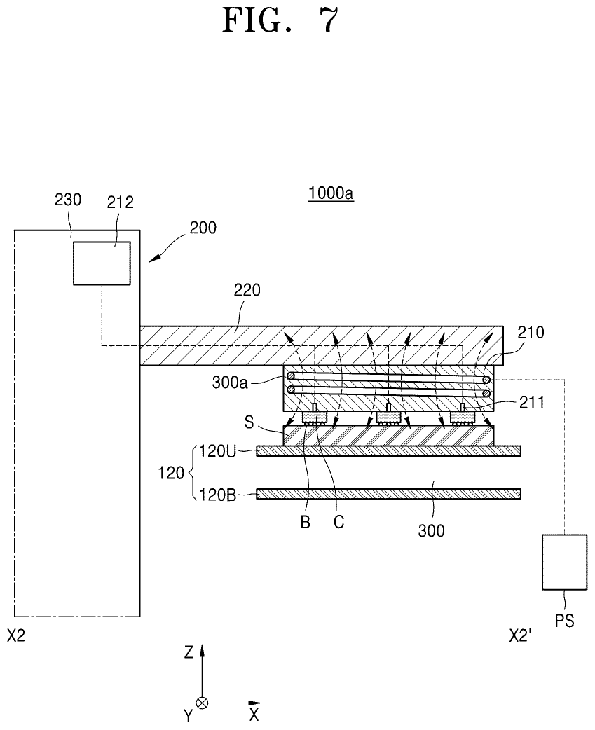

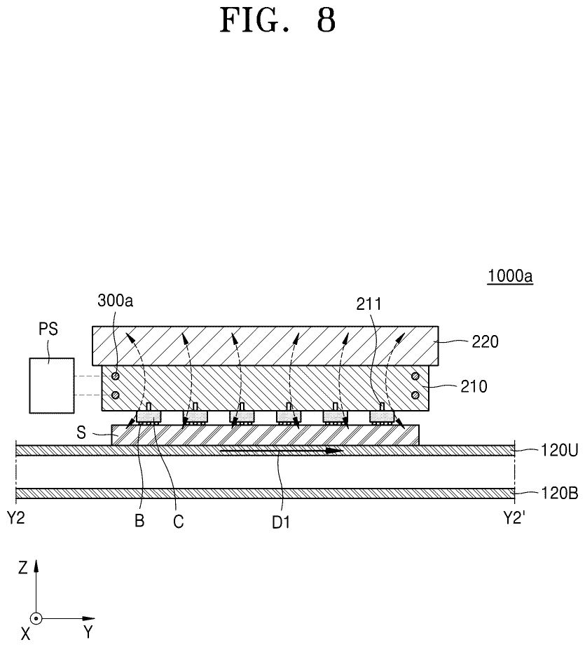

FIG. 6 is a schematic perspective view of a semiconductor reflow apparatus 1000a according to an embodiment. FIG. 7 is a schematic cross-sectional view of a portion of the semiconductor reflow apparatus 1000a of FIG. 6, taken along line X2-X2′ in FIG. 6. FIG. 8 is a schematic cross-sectional view of a portion of the semiconductor reflow apparatus 1000a of FIG. 6, taken along line Y2-Y2′ in FIG. 6.

The elements of the semiconductor reflow apparatus 1000a and the materials of the elements described herein may be substantially the same as or similar to those described herein with reference to FIG. 2, and repetitive descriptions thereof may be omitted.

The semiconductor reflow apparatus 1000a may include the conveyor 100, the pickup tool 200, and an induction heating coil 300a.

The induction heating coil 300a may include an inner through space. The induction heating coil 300a may be electrically connected to the power supply PS. The power supply PS may apply an alternating current to the induction heating coil 300a. When current is applied to the induction heating coil 300a, a magnetic field may be formed around the induction heating coil 300a. When current is applied to the induction heating coil 300a, the induction heating coil 300a may inductively heat a metal around the induction heating coil 300a.

The induction heating coil 300a may be disposed inside the head 210 of the pickup tool 200. The induction heating coil 300a may extend, within the head 210, along a side surface of the head 210. In some embodiments, the shape of the inner through space of the induction heating coil 300a may be the same as the shape of the bottom surface of the head 210. The area of the inner through space of the induction heating coil 300a may be less than the area of the bottom surface of the head 210.

However, embodiments are not limited thereto. The induction heating coil 300a may extend along an outer side surface of the head 210 of the pickup tool 200. In other words, the head 210 may be located in the inner through space of the induction heating coil 300a and the induction heating coil 300a may be attached to the head 210 and/or the head driver 220.

As the head 210 moves, the induction heating coil 300a may move along with the head 210. When the head 210 moves in the vertical direction (the Z direction) above the package substrate S and mounts the chip dies C on the package substrate S, the induction heating coil 300a embedded in the head 210 may move in the vertical direction (the Z direction) along with the head 210.

The induction heating coil 300a may be disposed inside the head 210 and may be fixed above the chip dies C while the chip dies C are being bonded to the package substrate S. Accordingly, when the chip dies C are attached to the head 210, the chip dies C may be self-aligned with the induction heating coil 300a, and the performance of the induction heating coil 300a heating the conductive bumps B may be increased.

In some embodiments, as show in FIG. 7, the induction heating coil 300a may be disposed inside the head 210 and a magnetic flux penetrating the inner through space of the induction heating coil 300a may be directed to the bottom surface of the head 210. In other words, the induction heating coil 300a may have a spiral shape extending substantially in the vertical direction (the Z direction).

However, embodiments are not limited thereto. The induction heating coil 300a may be arranged inside the head 210 such that magnetic flux penetrating the inner through space of the induction heating coil 300a is directed to the side surface of the head 210. In other words, the induction heating coil 300a may have a spiral shape extending substantially in the horizontal direction.

In some embodiments, the head 210 may be formed of a material, for example, including a non-metallic material. For example, the temperature of the head 210 may not be increased by the induction heating coil 300a. For example, the head 210 may include at least one of quartz or ceramic.

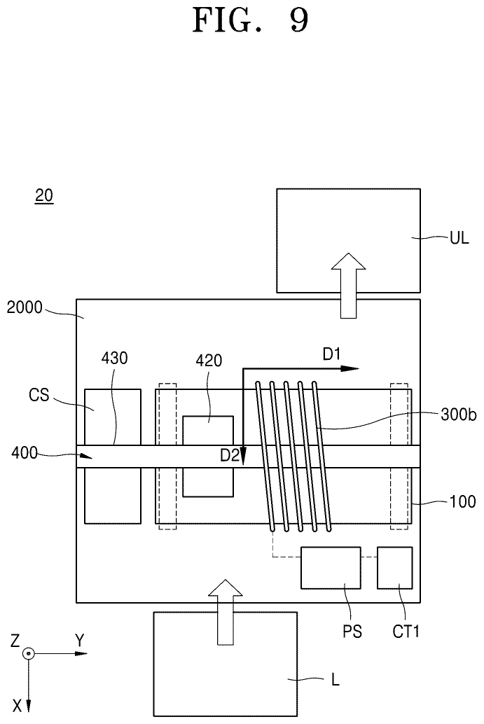

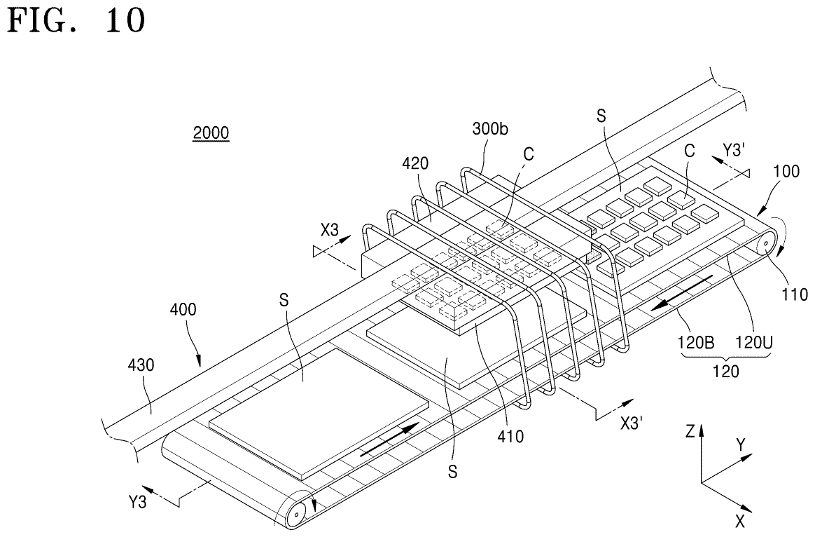

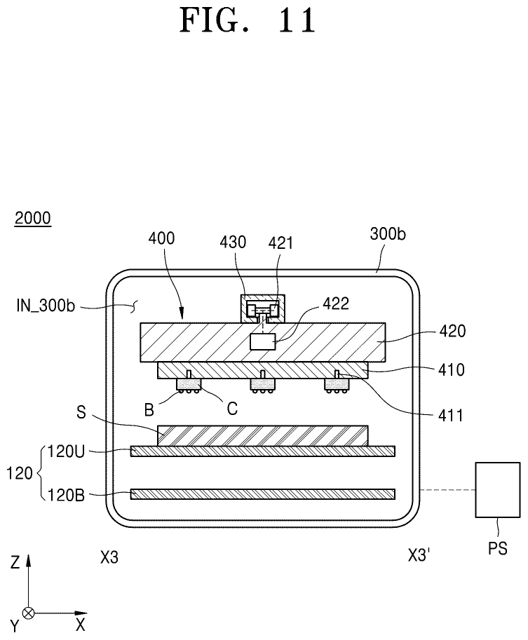

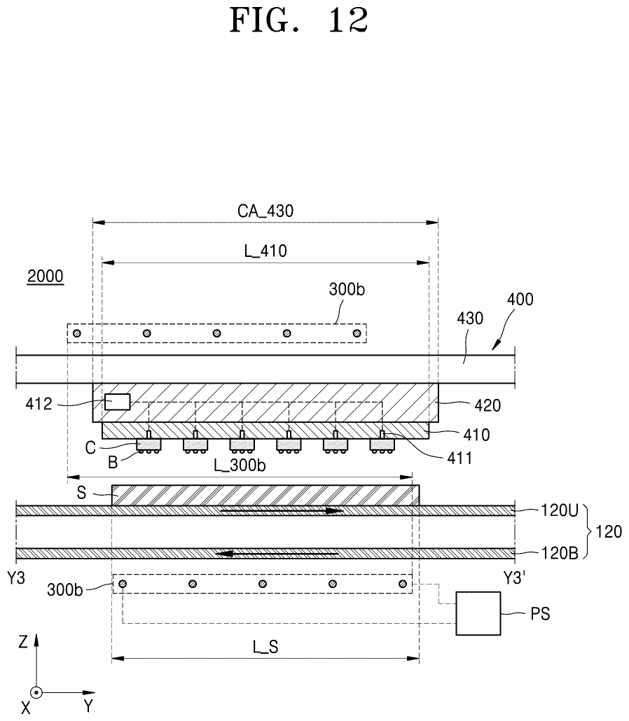

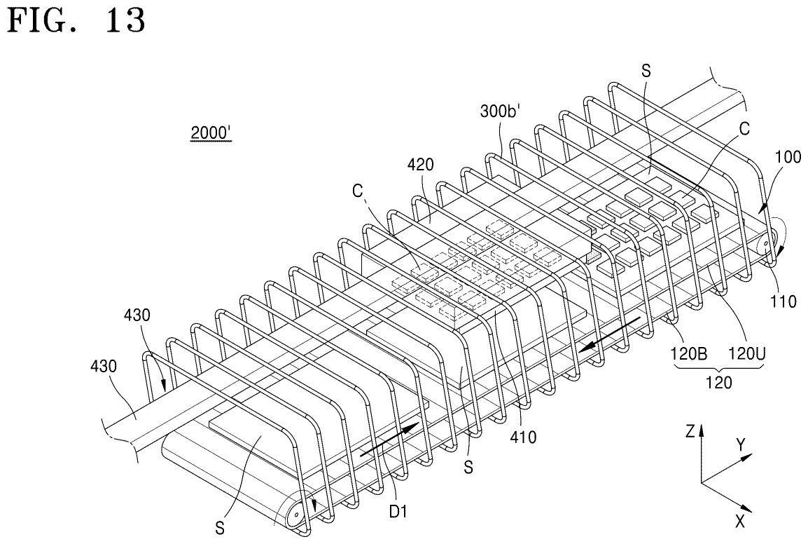

FIG. 9 is a schematic block diagram of a semiconductor package system 20 according to an embodiment. FIG. 10 is a schematic perspective view of a portion of a semiconductor reflow apparatus 2000 of the semiconductor package system 20 of FIG. 9. FIG. 11 is a schematic cross-sectional view of a portion of the semiconductor reflow apparatus 2000 of FIG. 10, taken along line X3-X3′ in FIG. 10. FIG. 12 is a schematic cross-sectional view of a portion of the semiconductor reflow apparatus 2000 of FIG. 10, taken along line Y3-Y3′ in FIG. 10.

Referring to FIG. 9, the semiconductor package system 20 may include a loader L, the semiconductor reflow apparatus 2000, and an unloader UL. The loader L may transfer a package substrate S (see FIG. 11) to the semiconductor reflow apparatus 2000. For example, the loader L may transfer the package substrate S to the conveyor 100 of the semiconductor reflow apparatus 2000.

The semiconductor reflow apparatus 2000 may mount a plurality of chip dies C (see FIG. 11) on the package substrate on the conveyor 100, carry out a reflow process, and bond the chip dies to the package substrate by melting a plurality of conductive bumps B (see FIG. 11). A semiconductor package manufactured by the semiconductor reflow apparatus 2000 by bonding the chip dies to the package substrate may be transferred to the unloader UL.

The semiconductor reflow apparatus 2000 is described in detail herein with reference to FIG. 10, FIG. 11, and FIG. 12.

Referring to FIGS. 10 to 12, the semiconductor reflow apparatus 2000 may include the conveyor 100, a pickup tool 400, and an induction heating coil 300b.

The elements of the semiconductor reflow apparatus 2000 and the materials of the elements described herein may be substantially the same as or similar to those described herein with reference to FIG. 2, and repetitive descriptions thereof may be omitted.

The conveyor 100 may have the package substrate S mounted thereon and may transport the package substrate S in the first direction D1. The conveyor 100 may include the pair of power shafts 110 and the belt 120. The power shafts 110 may be spaced apart from each other in the first direction D1. The power shafts 110 may rotate in the same direction with respect to the long axis. The belt 120 may be mounted on the pair of power shafts 110. The belt 120 may rotate as the pair of power shafts 110 rotates.

The pickup tool 400 may transport the chip dies C from a chip shuttle CS to a package substrate S. For example, an arrangement of the chip dies C disposed in the chip shuttle CS may be the same as an arrangement in which the chip dies C are to be mounted on the package substrate S. In other words, the pickup tool 400 may transfer the chip dies C to the package substrate S in the same arrangement as the chip dies C on the chip shuttle CS.

The pickup tool 400 may include a head 410, a body 420, and a traveling rail 430. The head 410 may be attached to the body 420 and may move along with the movement of the body 420. The body 420 may be mounted on the traveling rail 430 and may travel along the traveling rail 430.

The traveling rail 430 may extend lengthwise in the first direction D1. The traveling rail 430 may be disposed above the conveyor 100. In some embodiments, opposite ends of the traveling rail 430 may be respectively fixed to opposite sidewalls of the housing of the semiconductor reflow apparatus 2000, wherein the opposite sidewalls of the housing are spaced apart from each other in the first direction D1. However, embodiments are not limited thereto. The pickup tool 400 may be configured such that the traveling rail 430 may move in the vertical direction (the Z direction).

The traveling rail 430 may provide a movement path for the body 420 and the head 410. In other words, the body 420 and the head 410 may move along the traveling rail 430. In some embodiments, the chip shuttle CS may be spaced apart from the conveyor 100 in the first direction D1 and the traveling rail 430 may be disposed above the chip shuttle CS and the conveyor 100. The body 420 and the head 410, which may move in the first direction D1 along the traveling rail 430, may mount the chip dies C from the chip shuttle CS onto the package substrate S on the conveyor 100.

The head 410 may be configured to allow the chip dies C to be attached thereto or detached therefrom. For example, the head 410 may include a plurality of vacuum grooves 411. The vacuum grooves 411 may be disposed in the bottom of the head 410. The pickup tool 400 may generate a negative pressure in the vacuum grooves 411 to attach the chip dies C to the bottom surface of the head 410. The pickup tool 400 may remove the negative pressure from the vacuum grooves 411 to detach the chip dies C from the head 410. In some embodiments, the head 410 may be substantially the same as the head 210 described herein with reference to FIG. 4.

In some embodiments, the area of the bottom surface of the head 410 may be greater than the area of the top surface of the package substrate S. For example, a length L_410 of the head 410 in the first direction D1 may be greater than or equal to a length L_S of the package substrate S in the first direction D1 (see FIG. 12). The length of the head 410 in the second direction D2 may be greater than or equal to the length of the package substrate S in the second direction D2 (see FIG. 1 and FIG. 11). The chip dies C to be mounted on the package substrate S may be simultaneously attached to the head 410 such that the pickup tool 400 may simultaneously mount the chip dies C on the package substrate S.

In some embodiments, the length L_410 of the head 410 in the first direction D1 may be less than the length L_S of the package substrate S in the first direction D1 and the length of the head 210 in the second direction D2 may be greater than or equal to the length of the package substrate S in the second direction D2. The chip dies C arranged in line in the second direction D2 among the chip dies C to be mounted on the package substrate S may be simultaneously attached to the head 410 and mounted on the package substrate S.

The body 420 may have the head 410 attached to the bottom surface thereof. The body 420 may move along the traveling rail 430 with the head 410 attached thereto.

The body 420 may include a negative pressure generator 412. The negative pressure generator 412 may generate negative pressure in the vacuum grooves 411 of the head 410. The negative pressure generator 412 may be substantially the same as the negative pressure generator 212 described herein with reference to FIG. 4.

In some embodiments, the body 420 may include a traveling wheel 421 and a modulator 422 providing power to the traveling wheel 421 (see FIG. 11). In some embodiments, the traveling wheel 421 of the body 420 may be mounted on the traveling rail 430 such that the body 420 may move along the traveling rail 430 as the traveling wheel 421 rotates.

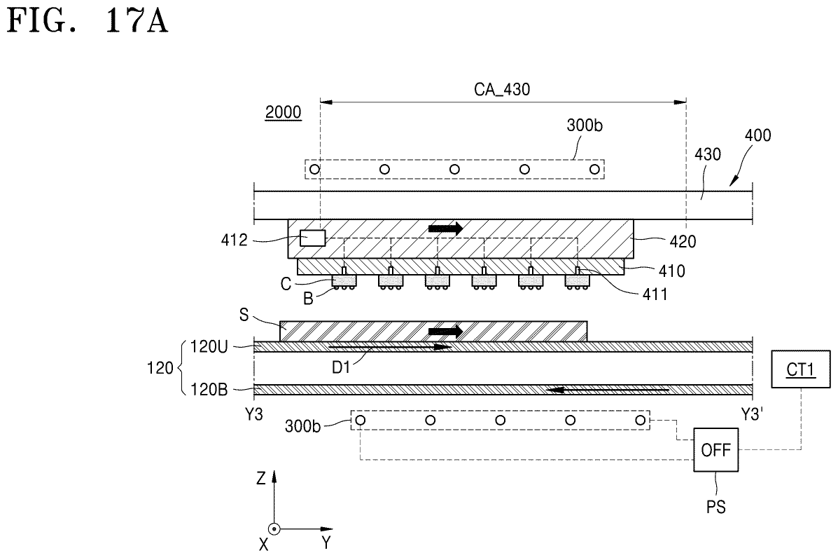

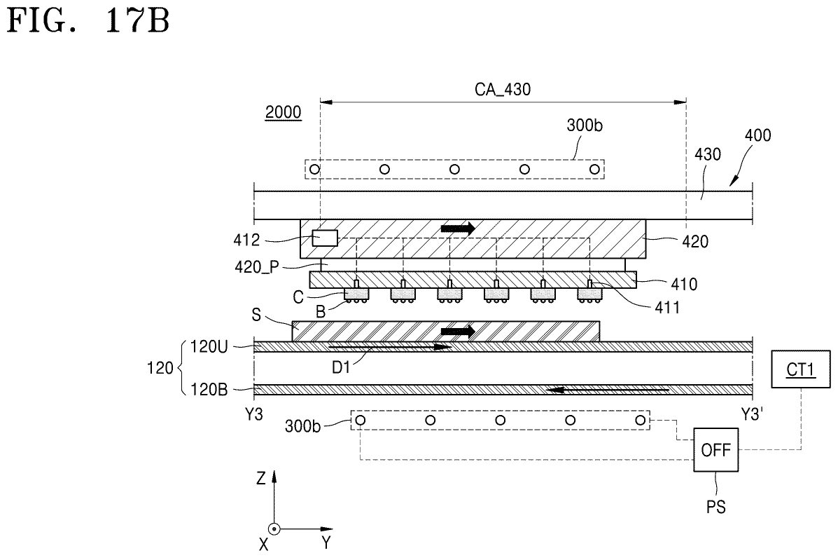

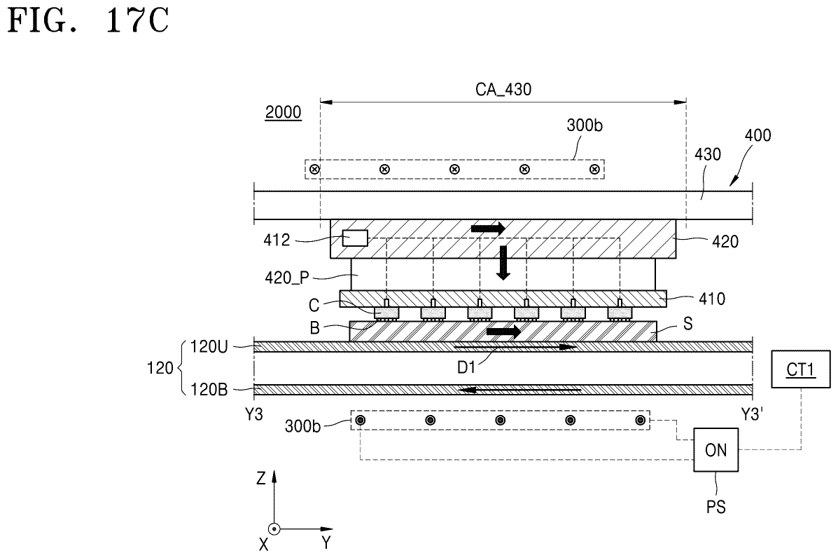

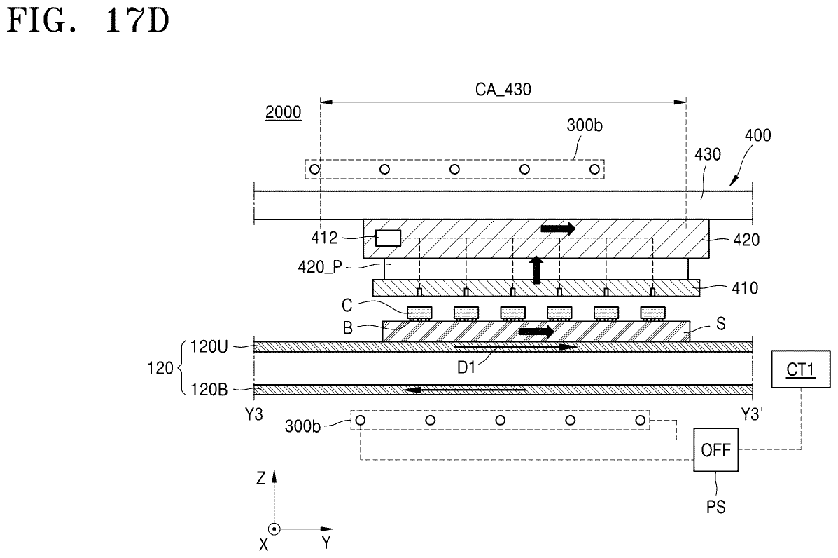

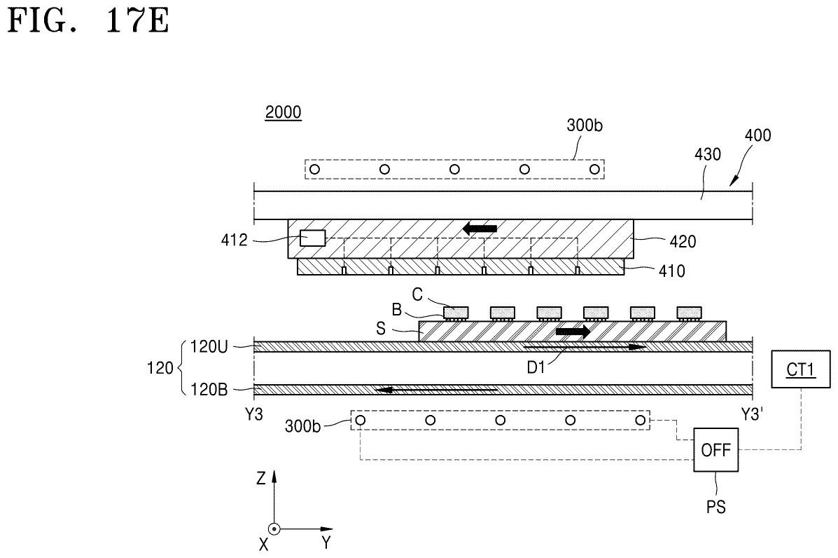

In some embodiments, the body 420 may include a pressing unit 420_P (see FIG. 17B). The pressing unit 420_P of the body 420 may protrude downwards from the bottom surface thereof in the vertical direction (the Z direction). For example, the pressing unit 420_P may move in and out of the body 420 in the vertical direction (the Z direction).

For example, the head 410 may be attached to the pressing unit 420_P of the body 420 and moved in the vertical direction (the Z direction) by the pressing unit 420_P of the body 420. When the pressing unit 420_P of the body 420 moves downwards from the bottom surface of the body 420, the head 410 may move downwards along with the pressing unit 420_P of the body 420. Accordingly, the vertical level of the head 410 may be changed through the pressing unit 420_P of the body 420.

In some embodiments, the body 420 may further include a controller (not shown). The controller of the body 420 may control the head 410 and the body 420 when the pickup tool 400 mounts the chip dies C on the package substrate S and presses a plurality of conductive bumps B. For example, the controller of the body 420 may control the negative pressure generator 412 such that the chip dies C may be attached to or detached from the head 410. For example, the controller of the body 420 may control the modulator 422 to control the location and the moving speed of the body 420 and the head 410 in the first direction D1. For example, the controller of the body 420 may control the pressing unit of the body 420 to control the vertical level of the head 410.

In some embodiments, the pickup tool 400 may be configured to mount the chip dies C on the package substrate S on the conveyor 100. For example, when the package substrate S is mounted on the conveyor 100, the package substrate S may not have the chip dies C mounted thereon. As the package substrate S moves along the conveyor 100, the chip dies C may be mounted on the package substrate S by the pickup tool 400.

In some embodiments, the pickup tool 400 may be configured such that the head 410 of the pickup tool 400 presses the package substrate S in the vertical direction (the Z direction) in a process of mounting the chip dies C on the package substrate S. For example, even after the chip dies C attached to the head 410 contact the package substrate S, the pickup tool 400 may continuously move the pressing unit of the body 420 downwards so that the head 410 moves downwards in the vertical direction (the Z direction).

In some embodiments, the pickup tool 400 may be configured such that the head 410 presses the package substrate S in the vertical direction (the Z direction) while the conductive bumps B are heated. The pickup tool 400 may be configured such that the head 410 presses the package substrate S in the vertical direction (the Z direction) during heating and melting of the conductive bumps B. For example, the induction heating coil 300b, the pickup tool 400 may move the head 410 downwards in the vertical direction (the Z direction) while the alternating current is turned on. The pickup tool 400 may be configured such that the head 410 presses the package substrate S in the vertical direction (the Z direction) while the conductive bumps B are cooled. For example, the induction heating coil 300b, the pickup tool 400 may move the head 410 downwards in the vertical direction (the Z direction) for at least a time after the alternating current is turned off.

As the head 410 moves downwards in the vertical direction (the Z direction), the head 410 may indirectly apply pressure to the package substrate S. During this process, the conductive bumps B below the chip dies C may receive the pressure. Through the process in which the pickup tool 400 presses the package substrate S, the melting point of the conductive bumps B may be lowered, and the quality of a reflow process may be increased.

The induction heating coil 300b may include an inner through space IN_300b (see FIG. 11). The induction heating coil 300b may be electrically connected to a power supply PS that applies alternating current to the induction heating coil 300b. When current is applied to the induction heating coil 300b, a magnetic field may be formed around the induction heating coil 300b. When alternating current is applied to the induction heating coil 300b, the induction heating coil 300b may inductively heat a metal around the induction heating coil 300b.

The conveyor 100 and the traveling rail 430 of the pickup tool 400 may pass through the inner through space IN_300b of the induction heating coil 300b. In other words, a portion of the conveyor 100 and a portion of the traveling rail 430 may be disposed in the inner through space IN_300b of the induction heating coil 300b. In some embodiments, the induction heating coil 300b may be arranged to surround portions of the conveyor 100 and the traveling rail 430. When current is applied to the induction heating coil 300b, the direction of the magnetic field passing through the inner through space IN_300b of the induction heating coil 300b may be parallel with the first direction D1. For example, the induction heating coil 300b may have a spiral shape extending substantially in the first direction D1.

Although it is illustrated in FIG. 11 that the inner through space IN_300b of the induction heating coil 300b has a rectangular shape, the shape of the inner through space IN_300b of the induction heating coil 300b is not limited thereto.

In some embodiments, the induction heating coil 300b may have a spiral shape extending substantially in the first direction D1. A length L_300b of the induction heating coil 300b in the first direction D1 may be greater than the length L_410 of the head 410 of the pickup tool 400 in the first direction D1. The induction heating coil 300b may simultaneously heat the conductive bump B disposed below the chip dies C attached to the head 410.

A portion of the traveling rail 430, in which the head 410 is located while the chip dies C are being bonded to the package substrate S, may be referred to as a contact section CA_430 of the traveling rail 430 (see FIG. 12). In some embodiments, the contact section CA_430 of the traveling rail 430 may correspond to the location of the head 410 while the head 410 is mounting the chip dies C on the package substrate S and pressing the package substrate S.

For example, when the package substrate S and the head 410 are in a stopped state while the chip dies C are being bonded to the package substrate S, the contact section CA_430 of the traveling rail 430 may correspond to the location of the head 410 when the chip dies C are mounted on the package substrate S.

However, as shown in FIGS. 17A to 17E, when the package substrate S and the head 410 move while the chip dies C are being bonded to the package substrate S, the contact section CA_430 of the traveling rail 430 may range from the location of the head 410 when the chip dies C contact the package substrate S to the location of the head 410 when the chip dies C are detached from the head 410.

In some embodiments, at least a portion of the contact section CA_430 of the traveling rail 430 may be located in the inner through space IN_300b of the induction heating coil 300b. For example, when the entirety of the contact section CA_430 of the traveling rail 430 is located in the inner through space IN_300b of the induction heating coil 300b, the conductive bumps B may be simultaneously heated by the induction heating coil 300b in a reflow operation.

For example, during the reflow operation, when the package substrate S and the head 410 move in the first direction D1, a first portion of the contact section CA_430 of the traveling rail 430 may be located in the inner through space IN_300b of the induction heating coil 300b and second portion of the contact section CA_430 of the traveling rail 430 may be located outside the inner through space IN_300b of the induction heating coil 300b. During the reflow operation, the package substrate S and the head 410 may pass through the inner through space IN_300b of the induction heating coil 300b. Accordingly, the conductive bumps B may be heated in the order in which the conductive bumps B pass through the inner through space IN_300b of the induction heating coil 300b.

The semiconductor reflow apparatus 2000 may apply alternating current to the induction heating coil 300b, thereby increasing the temperature of the conductive bumps B. Other components may not be heated. In other words, the semiconductor reflow apparatus 2000 may increase temperature only in a small area through induction heat, thereby reducing a reflow process time. For example, the semiconductor reflow apparatus 2000 may heat the conductive bumps B in about 20 seconds during a reflow operation.

In addition, the semiconductor reflow apparatus 2000 may not expose the chip dies C and the package substrate S to high temperature for a long time, and may suppress defects from occurring in a semiconductor package due to deformation of the chip dies C and/or the package substrate S.

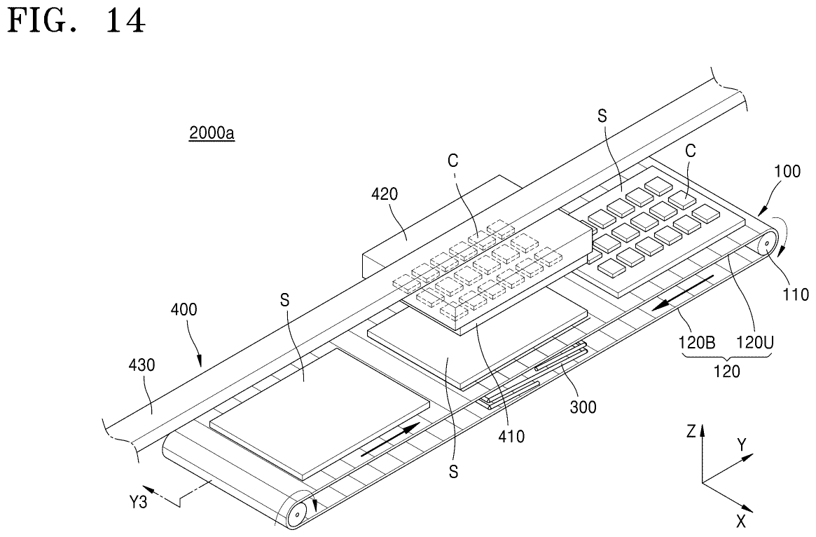

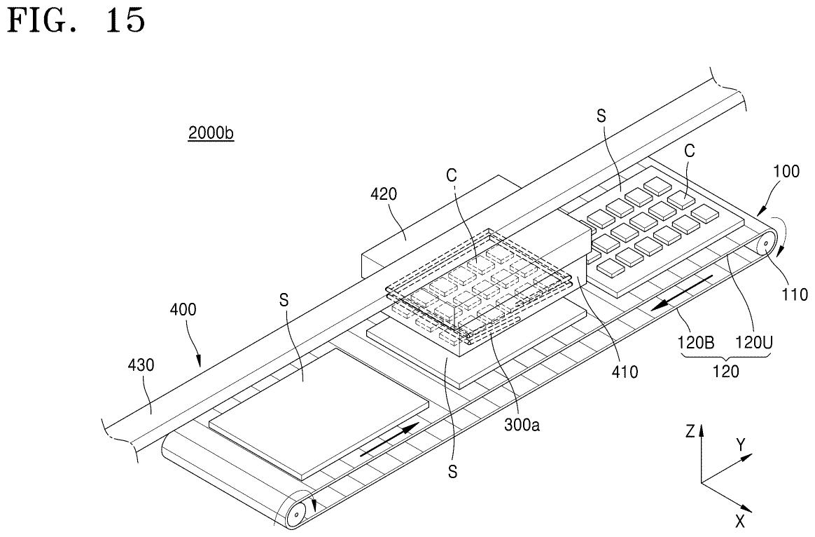

FIG. 13 is a schematic perspective view of a portion of a semiconductor reflow apparatus 2000′ according to an embodiment. FIG. 14 is a schematic perspective view of a portion of a semiconductor reflow apparatus 2000a according to an embodiment. FIG. 15 is a schematic perspective view of a portion of a semiconductor reflow apparatus 2000b according to an embodiment.

The elements of the semiconductor reflow apparatuses 2000′, 2000a, and 2000b and the materials of the elements described herein may be substantially the same as or similar to those described herein with reference to FIG. 10, and repetitive descriptions thereof may be omitted.

Referring to FIG. 13, the semiconductor reflow apparatus 2000′ may include an induction heating coil 300b′. The induction heating coil 300b′ may receive alternating current from a power supply and heat a plurality of conductive bumps. The induction heating coil 300b′ may receive alternating current from a power supply and melt the plurality of conductive bumps.

The induction heating coil 300b′ may include an inner through space. At least portions of the conveyor 100 and the traveling rail 430 may be disposed the inner through space of the induction heating coil 300b′. For example, the induction heating coil 300b′ may surround the conveyor 100 and the traveling rail 430.

In some embodiments, the induction heating coil 300b′ may have a spiral shape extending substantially in the first direction D1. For example, the length of the induction heating coil 300b′ in the first direction D1 may be greater than or equal to the length of the conveyor 100 in the first direction D1. The induction heating coil 300b′ may entirely surround the conveyor 100. In some embodiments, a pair of power shafts 110 of the conveyor 100 may be disposed in the inner through space of the induction heating coil 300b′.

Referring to FIG. 14, the semiconductor reflow apparatus 2000a may include the induction heating coil 300. The induction heating coil 300 may receive alternating current from a power supply and heat a plurality of conductive bumps. In some embodiments, the induction heating coil 300 may be substantially the same as the induction heating coil 300 described herein with reference to FIG. 2.

The induction heating coil 300 may have an inner through space and may include a single layer or multiple layers. The induction heating coil 300 may be disposed below the upper section 120U of the belt 120. The induction heating coil 300 may be spaced apart from the belt 120. In other words, the induction heating coil 300 may have a constant position, and the belt 120 may travel within the induction heating coil 300.

For example, the induction heating coil 300 may be disposed between the upper section 120U and the lower section 120B of the belt 120. However, embodiments are not limited thereto. The induction heating coil 300 may be disposed below the lower section 120B of the belt 120, that is, below the conveyor 100.

In some embodiments, as shown in FIG. 2, the induction heating coil 300 may be arranged such that a magnetic field passing through the inner through space of the induction heating coil 300 may be directed to the upper section 120U of the belt 120. In other words, the induction heating coil 300 may have a spiral shape extending substantially in the vertical direction (the Z direction).

However, embodiments are not limited thereto. The induction heating coil 300 may be arranged such that a magnetic field passing through the inner through space of the induction heating coil 300 may be in the first direction D1. In other words, the induction heating coil 300 may have a spiral shape extending substantially in the horizontal direction.

Referring to FIG. 15, the semiconductor reflow apparatus 2000b may include the induction heating coil 300a. The induction heating coil 300a may receive alternating current from a power supply and heat a plurality of conductive bumps. The induction heating coil 300a may heat the plurality of conductive bumps to a melting point thereof. In some embodiments, the induction heating coil 300a may be substantially the same as the induction heating coil 300a described herein with reference to FIG. 6.

The induction heating coil 300a may be disposed inside the head 210 of the pickup tool 200. The induction heating coil 300a may extend in the head 210 along the side surface of the head 210. In some embodiments, the shape of the inner through space of the induction heating coil 300a may be the same as the shape of the bottom surface of the head 210. The area of the inner through space of the induction heating coil 300a may be less than the area of the bottom surface of the head 210.

However, embodiments are not limited thereto. The induction heating coil 300a may extend along the outer side surface of the head 210 of the pickup tool 200. In other words, the head 210 may be located in the inner through space of the induction heating coil 300a and the induction heating coil 300a may be attached to the head 210.

As the head 210 moves, the induction heating coil 300a may move along with the head 210. When the head 210 moves in the vertical direction (the Z direction) above the package substrate S and mounts the chip dies C on the package substrate S, the induction heating coil 300a embedded in the head 210 may move in the vertical direction (the Z direction) along with the head 210.

In some embodiments, as shown in FIG. 7, the induction heating coil 300a may be arranged inside the head 210 such that magnetic flux penetrating the inner through space of the induction heating coil 300a may be directed to the bottom surface of the head 210. In other words, the induction heating coil 300a may have a spiral shape extending substantially in the vertical direction (the Z direction).

However, embodiments are not limited thereto. The induction heating coil 300a may be arranged inside the head 210 such that magnetic flux penetrating the inner through space of the induction heating coil 300a may be directed to the side surface of the head 210. In other words, the induction heating coil 300a may have a spiral shape extending substantially in the horizontal direction.

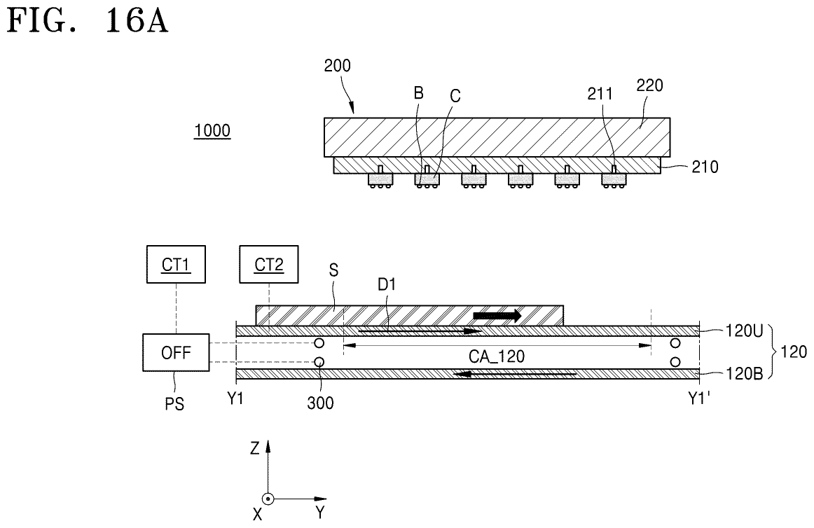

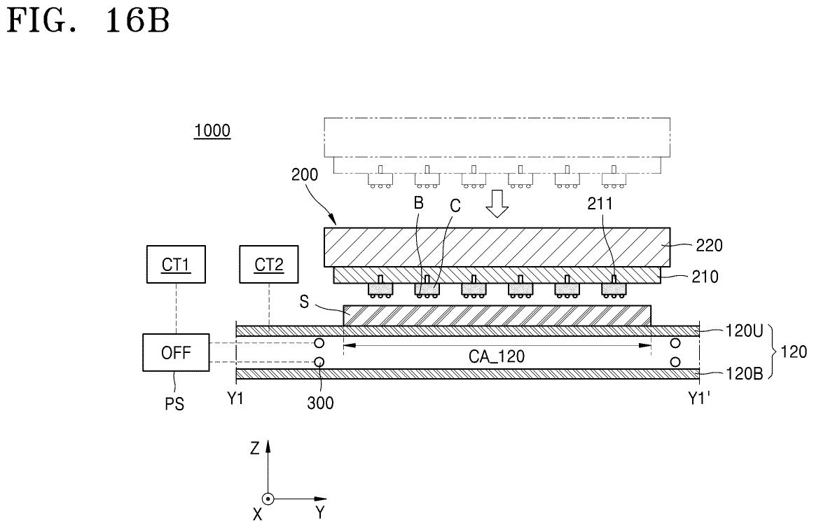

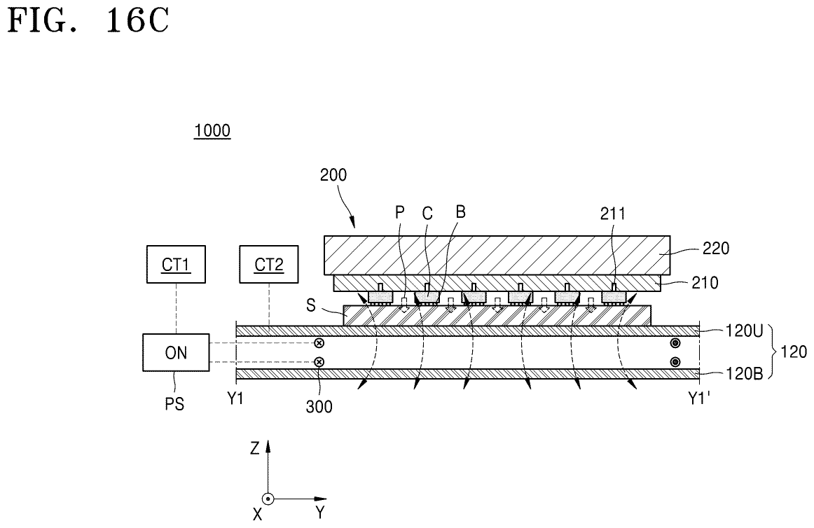

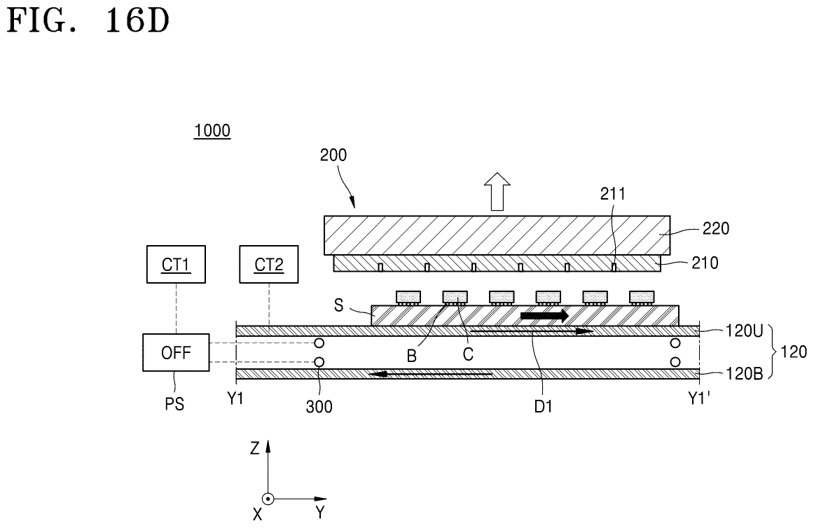

FIG. 16A, FIG. 16B, FIG. 16C, and FIG. 16D are diagrams illustrating a reflow process of the semiconductor reflow apparatus 1000, according to an embodiment.

In detail, FIGS. 16A to 16D are cross-sectional views of sequential stages in the reflow process of the semiconductor reflow apparatus 1000, taken along line Y1-Y1′ of FIG. 2.

The elements of the semiconductor reflow apparatus 1000 and the materials of the elements described herein may be substantially the same as or similar to those described herein with reference to FIG. 2, and repetitive descriptions thereof may be omitted.

Referring to FIG. 16A, as the belt 120 of the conveyor 100 rotates, the package substrate S on the upper section 120U of the belt 120 may move in the first direction D1. The chip dies C including the conductive bumps B have been attached to the bottom surface of the head 210 of the pickup tool 200. The chip dies C may be disposed above the contact section CA_120 of the belt 120 until the package substrate S reaches the contact section CA_120 of the belt 120.

Referring to FIG. 16B, when the package substrate S reaches the contact section CA_120 of the belt 120, the second controller CT2 may stop the operation of the conveyor 100. In other words, the second controller CT2 may stop the rotation of the belt 120 of the conveyor 100 by stopping the rotation of the pair of power shafts 110 (in FIG. 2). In other words, when the package substrate S reaches the contact section CA_120 of the belt 120, the transportation of the package substrate S may be stopped.

For example, the second controller CT2 may stop the operation of the conveyor 100, and the chip dies C may be mounted on the package substrate S. For example, when the chip dies C contact the package substrate S, the second controller CT2 may stop the operation of the conveyor 100 so that the package substrate S may be in a stopped state.

When the package substrate S reaches the contact section CA_120 of the belt 120, the head driver 220 of the pickup tool 200 may move downwards in the vertical direction (the Z direction) to move the head 210 toward the package substrate S.

While the pickup tool 200 is mounting the chip dies C on the package substrate S, the head 210 may move in the vertical direction (the Z direction) without moving in the first direction D1. Accordingly, in the process of mounting the chip dies C on the package substrate S, the chip dies C may be aligned with the package substrate S.

Referring to FIG. 16C, the chip dies C may be mounted on the package substrate S by the pickup tool 200, and the head driver 220 may continuously move downwards in the vertical direction (the Z direction) to apply pressure P to the chip dies C and the package substrate S. As the head 210 is moved downwards by the head driver 220, the conductive bumps B between the chip dies C and the package substrate S may receive the pressure P.

After the pickup tool 200 mounts the chip dies C on the package substrate S, the first controller CT1 may turn on the power supply PS. The induction heating coil 300 may receive alternating current from the power supply PS and heat the conductive bumps B.

In a reflow operation in which the conductive bumps B are melted, the conductive bumps B may be pressed by the pickup tool 200 and heated by the induction heating coil 300.

Referring to FIG. 16D, when the conductive bumps B are melted and the package substrate S and the chip dies C have been bonded, the pickup tool 200 may detach the chip die C from the head 210 by removing negative pressure formed in the vacuum grooves 211 of the head 210. Thereafter, the pickup tool 200 may separate the head 210 from the chip dies C by moving the head driver 220 upwards in the vertical direction (the Z direction).

When the conductive bumps B are melted and the package substrate S and the chip dies C have been bonded, the first controller CT1 may turn off the power supply PS. When current is not applied to the induction heating coil 300, induction heating may not occur around the induction heating coil 300. Accordingly, the induction heating coil 300 may be turned off and heating may be stopped.

When the head 210 is separated from the chip dies C, the second controller CT2 may resume the operation of the conveyor 100. The package substrate S having the chip dies C bonded thereto may be transported in the first direction D1 by the rotation of the belt 120 of the conveyor 100.

FIG. 17A, FIG. 17B, FIG. 17C, FIG. 17D, and FIG. 17E are diagrams illustrating a reflow process of the semiconductor reflow apparatus 2000, according to an embodiment.

In detail, FIGS. 17A to 17E are cross-sectional views of sequential stages in the reflow process of the semiconductor reflow apparatus 2000, taken along line Y3-Y3′ of FIG. 10.

The elements of the semiconductor reflow apparatus 2000 and the materials of the elements described herein may be substantially the same as or similar to those described herein with reference to FIG. 10, and repetitive descriptions thereof may be omitted.

Referring to FIG. 17A, the package substrate S on the conveyor 100 may be transported in the first direction D1 as the belt 120 of the conveyor 100 rotates. In some embodiments, the transport speed of the package substrate S may be constant at a first speed.

Before the package substrate S on the conveyor 100 reaches the contact section CA_430 of the traveling rail 430, the head 410 of the pickup tool 400 may allow the chip dies C to be attached thereto from the chip shuttle CS (in FIG. 9) and may move to the contact section CA_430 of the traveling rail 430.

Referring to FIGS. 17B to 17D, the chip dies C may be bonded to the package substrate S by mounting the chip dies C on the package substrate S and melting the conductive bumps B.

Referring to FIGS. 17B to 17D, in the mounting and reflow operations of the semiconductor reflow apparatus 2000, the package substrate S and the pickup tool 400 may move in the first direction D1. In other words, in the mounting and reflow operations of the semiconductor reflow apparatus 2000, the conveyor 100 may not stop, the package substrate S may be transported at the first speed, and the head 410 of the pickup tool 400 may move at the first speed in the first direction D1 in accordance with the speed of the package substrate S.

In other words, while the pickup tool 400 is bonding the chip dies C to the package substrate S, the package substrate S may move at the first speed in the first direction D1 and the head 410 may also move at the first speed that is the same as the first speed of the package substrate S in the first direction D1.

In the mounting and reflow operations performed by the semiconductor reflow apparatus 2000 on the chip dies C and the package substrate S, the transport speed of the package substrate S may be constant so that the semiconductor package production efficiency of the semiconductor reflow apparatus 2000 may be increased.

Referring to FIG. 17B, the pressing unit 420_P of the body 420 of the pickup tool 400 may descend, thereby moving the head 410 in the vertical direction (the Z direction). The chip dies C attached to the head 410 may be mounted on the package substrate S by moving the pressing unit 420_P of the pickup tool 400 in the vertical direction (the Z direction).

For example, the pressing unit 420_P may begin to descend before the body 420 reaches the contact section CA_430 of the traveling rail 430. For example, the descent time and speed of the pressing unit 420_P may be set based on the transport speed of the package substrate S and the moving speed of the body 420.

Referring to FIG. 17C, after mounting the chip dies C on the package substrate S, the pickup tool 400 may continuously move the pressing unit 420_P downwards for a time such that the head 410 may apply pressure P to the package substrate S. As the head 410 is moved downwards by the pressing unit 420_P, the conductive bumps B between the chip dies C and the package substrate S may receive the pressure P.

After the pickup tool 400 mounts the chip dies C on the package substrate S, the first controller CT1 may turn on the power supply PS. The induction heating coil 300b may receive alternating current from the power supply PS and heat the conductive bumps B.

In a reflow operation in which the conductive bumps B are melted, the conductive bumps B may be pressed by the pickup tool 400 and heated by the induction heating coil 300b.

Referring to FIG. 17D, when the conductive bumps B are melted and the package substrate S and the chip dies C have been bonded, the pickup tool 400 may detach the chip die C from the head 410 by removing negative pressure formed in the vacuum grooves 411 of the head 410. Thereafter, the pickup tool 400 may separate the head 410 from the chip dies C by moving the pressing unit 420_P upwards in the vertical direction (the Z direction).

When the conductive bumps B are melted and the package substrate S and the chip dies C have been bonded, the first controller CT1 may turn off the power supply PS. When current is not applied to the induction heating coil 300b, induction heating may not occur around the induction heating coil 300b. Accordingly, the induction heating coil 300b may be turned off, and heating may be stopped.

The package substrate S, to which the chip dies C are bonded, may continuously move in the first direction D1. The pickup tool 400, from which the chip dies C are detached, may move to the chip shuttle CS (in FIG. 9) for a next operation (if any).

While the inventive concept has been particularly shown and described with reference to embodiments thereof, it will be understood that various changes in form and details may be made therein without departing from the spirit and scope of the following claims.

What is claimed is:

1. A semiconductor reflow apparatus comprising:
a conveyor comprising a laterally moveable surface configured to move in a first direction;
a pickup tool including a head disposed above the conveyor; and
an induction heating coil configured to generate a magnetic field in a direction passing through a surface of the conveyor,
wherein the pickup tool is further configured to move the head in a vertical direction toward the conveyor.

2. The semiconductor reflow apparatus of claim 1, wherein
the conveyor includes a pair of power shafts spaced apart from each other in the first direction and a belt mounted on the pair of power shafts,
the belt comprises an upper section disposed above the pair of power shafts and a lower section disposed below the pair of power shafts, and
the induction heating coil is located below the upper section of the belt.

3. The semiconductor reflow apparatus of claim 2, wherein
the induction heating coil is disposed between the upper section and the lower section of the belt, and
the induction heating coil is spaced apart from the belt in the vertical direction.

4. The semiconductor reflow apparatus of claim 2, wherein
the conveyor is configured to have a package substrate mounted on the laterally moveable surface and transport the package substrate in the first direction,
the pickup tool including the head is configured to secure a plurality of chip dies to the head, the pickup tool being configured to mount the plurality of chip dies on the package substrate mounted on the laterally moveable surface, and
when a portion of the belt where the package substrate is located while the plurality of chip dies are being bonded to the package substrate is a contact section of the belt, and
an inner through space of the induction heating coil is disposed below the contact section of the belt.

5. The semiconductor reflow apparatus of claim 1, wherein the induction heating coil is disposed inside the head of the pickup tool.

6. The semiconductor reflow apparatus of claim 5, wherein the head of the pickup tool includes a non-metallic material.

7. The semiconductor reflow apparatus of claim 1, wherein an area of the head of the pickup tool is less than or equal to an area of an inner through space of the induction heating coil.

8. The semiconductor reflow apparatus of claim 1, further comprising:
a power supply configured to apply alternating current to the induction heating coil; and
a first controller configured to control the power supply,
wherein the first controller is further configured to control the power supply to apply the alternating current to the induction heating coil when the head of the pickup tool mounts a plurality of chip dies on a package substrate mounted on the laterally moveable surface.

9. The semiconductor reflow apparatus of claim 1, further comprising a second controller configured to control an operation of the conveyor,
wherein the second controller is further configured to stop the operation of the conveyor when a package substrate mounted on the laterally moveable surface is disposed below the head of the pickup tool.

10. The semiconductor reflow apparatus of claim 1, wherein the head of the pickup tool includes a plurality of vacuum grooves.

11. A semiconductor reflow apparatus for melting a plurality of bumps disposed between a package substrate and a plurality of chip dies, the semiconductor reflow apparatus comprising:
a conveyor configured to have the package substrate mounted on the conveyor and transport the package substrate in a first direction;
a pickup tool including a head and a traveling rail, the head being configured to capture the plurality of chip dies, and the traveling rail extending in the first direction, providing a movement path for the head, and being disposed above the conveyor; and
an induction heating coil configured to heat the plurality of bumps through eddy current and bond the plurality of chip dies to the package substrate,
wherein
the pickup tool is configured to mount the plurality of chip dies on the package substrate mounted on the conveyor, and
the pickup tool is further configured to press the plurality of chip dies captured by the head into the package substrate in a vertical direction in a process of heating the plurality of bumps.

12. The semiconductor reflow apparatus of claim 11, wherein
the induction heating coil includes an inner through space, and
portions of the conveyor and the traveling rail of the pickup tool are disposed in an inner through space of the induction heating coil.

13. The semiconductor reflow apparatus of claim 12, wherein a length of the induction heating coil in the first direction is greater than a length of the head of the pickup tool in the first direction.

14. The semiconductor reflow apparatus of claim 12, wherein an area of a bottom surface of the head of the pickup tool is greater than an area of a top surface of the package substrate.

15. The semiconductor reflow apparatus of claim 12, wherein,
when a transport speed of the package substrate on the conveyor is a first speed,
the conveyor is further configured to transport the package substrate at the first speed in the first direction while the plurality of chip dies are being bonded to the package substrate, and
the pickup tool is further configured to move the head at the first speed in the first direction while the plurality of chip dies are being bonded to the package substrate.

16. The semiconductor reflow apparatus of claim 15, wherein,
when a portion of the traveling rail where the head is located while the plurality of chip dies are being bonded to the package substrate is a contact section of the traveling rail,
at least a portion of the contact section of the traveling rail is disposed in the inner through space of the induction heating coil.

17. The semiconductor reflow apparatus of claim 11, wherein
the induction heating coil includes an inner through space, and
the conveyor is disposed in the inner through space of the induction heating coil.

18. A semiconductor reflow apparatus for melting a plurality of bumps disposed between a package substrate and a plurality of chip dies, the semiconductor reflow apparatus comprising:
a conveyor configured to have the package substrate mounted on the conveyor, the conveyor including a pair of power shafts spaced apart from each other in a first direction and a belt mounted on the pair of power shafts;
a pickup tool including a head configured to capture the plurality of chip dies, the pickup tool being configured to mount the plurality of chip dies on the package substrate on the conveyor;
an induction heating coil configured to heat the plurality of bumps through eddy current and bond the plurality of chip dies to the package substrate; and
a power supply electrically connected to the induction heating coil,
wherein,
when a portion of the belt where the package substrate is located while the plurality of chip dies are being bonded to the package substrate is a contact section of the belt,
the induction heating coil overlaps the contact section of the belt in a vertical direction, and
the pickup tool is further configured to press the plurality of chip dies captured by the head into the package substrate in the vertical direction while the power supply is applying alternating current to the induction heating coil.

19. The semiconductor reflow apparatus of claim 18, further comprising:
a first controller configured to control the power supply; and
a second controller configured to control an operation of the conveyor,
wherein the second controller is further configured to stop the operation of the conveyor when the package substrate is disposed below the head of the pickup tool, and
the first controller is further configured to turn on the power supply when the operation of the conveyor stops.

20. The semiconductor reflow apparatus of claim 18, wherein the pickup tool further includes a traveling rail disposed above the conveyor, the traveling rail extending in the first direction and providing a movement path for the head.
